(19) United States
(12) Patent Application Publication
(10) Pub. No.: US 2013/0313017 A1
(43) Pub. Date: Nov. 28, 2013

(54) HOUSING AND ELECTRONIC DEVICE USING THE HOUSING

(71) Applicants: SHENZHEN FUTAIHONG PRECISION INDUSTRY CO., LTD., Shenzhen (CN); FIH (HONG KONG) LIMITED, Kowloon (HK)

(72) Inventor: YU-GUANG ZHU, Shenzhen (CN)

(73) Assignees: FIH (HONG KONG) LIMITED, Kowloon (HK); SHENZHEN FUTAIHONG PRECISION INDUSTRY CO., LTD., Shenzhen (CN)

(21) Appl. No.: 13/848,164

(22) Filed: Mar. 21, 2013

(30) Foreign Application Priority Data
May 25, 2012 (CN) 201210165617.X

(51) Int. Cl. H05K 5/02

(52) U.S. Cl. CPC H05K 5/02
USPC 174/520

(57) ABSTRACT

A housing includes a substrate, a decorative layer disposed on one surface of the substrate, and a metallic decorative element disposed on the decorative layer. A portion of the decorative layer defines a corona layer; the corona layer contains polarized molecules. The metallic decorative element is bonded to the corona layer. An electronic device using the housing is also described.

### BACKGROUND

1. Technical Field

The present disclosure relates to a housing and an electronic device using the housing.

2. Description of Related Art

Housings of electronic devices, such as mobile phones, are commonly covered by decorative layers. Spray painting is now widely used to form the decorative layers. However, the paint layer formed by spray painting has a poor bond with metallic decorative elements, thus it is difficult to dispose a metallic decorative element to the paint layer to further decorate the housing.

Therefore, there is room for improvement within the art.

### BRIEF DESCRIPTION OF THE DRAWING

Many aspects of the disclosure can be better understood with reference to the following figure. The components in the figure are not necessarily drawn to scale, the emphasis instead being placed upon clearly illustrating the principles of the disclosure.

FIG. 1 is a schematic view of an electronic device having a housing in accordance with an exemplary embodiment.

FIG. 2 is a partial cross-sectional view of the housing of FIG. 1.

FIG. 3 is a cross-sectional view of the housing of FIG. 1.

### DETAILED DESCRIPTION

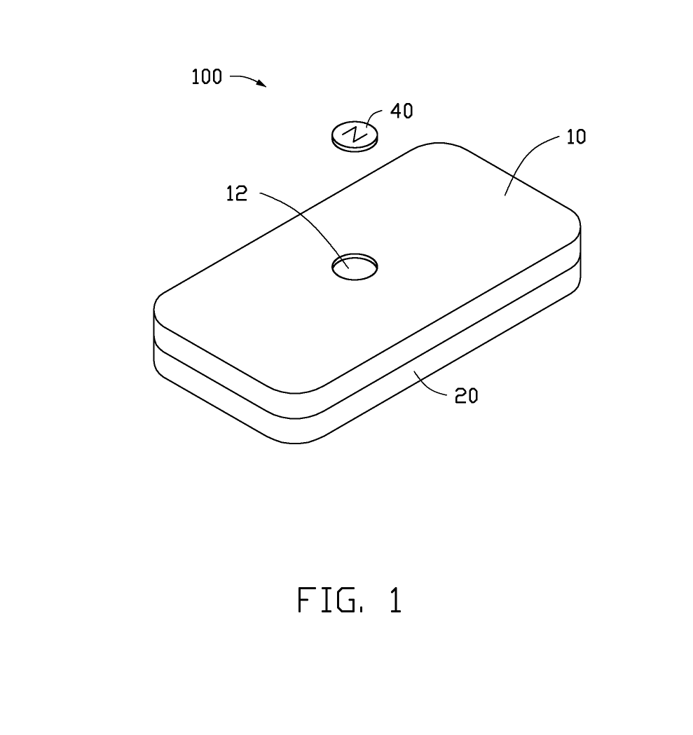

FIG. 1 is an electronic device 100 according to an exemplary embodiment. The electronic device 100 may be a mobile phone, a personal digital assistant (PDA), or a notebook computer. The exemplary embodiment uses a mobile phone as an example to describe the electronic device 100.

The electronic device 100 includes a main body 20 and a housing 10 assembled to the main body 20.

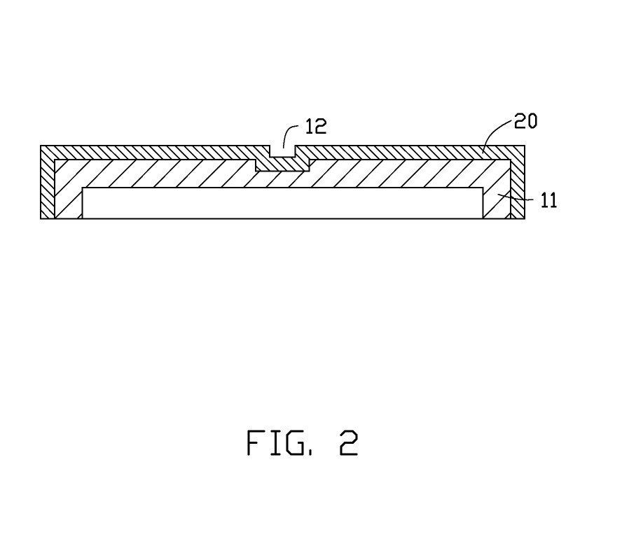

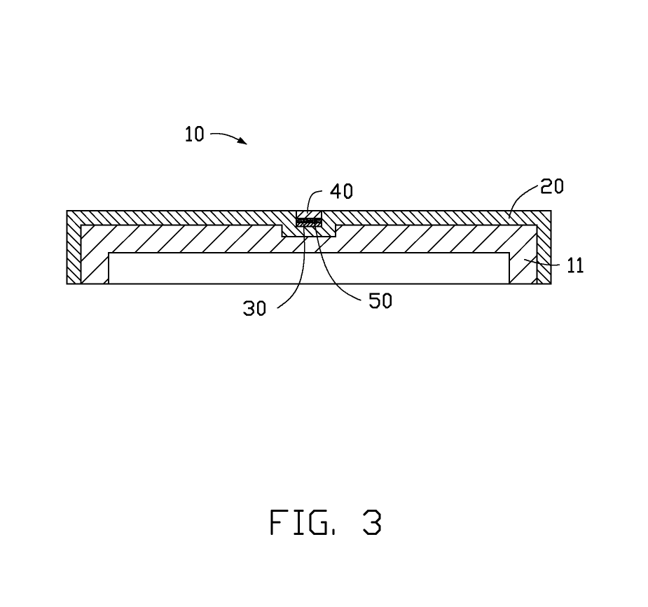

FIGS. 2-3 show that the housing 10 includes a substrate 11, a decorative layer 20, a corona layer 30, a metallic decorative element 40, and an adhesive layer 50.

The substrate 11 may be made of plastic, metal, or ceramic. The substrate 11 defines a receiving groove 12 in one surface of the substrate 11 opposite to the main body 20.

The decorative layer 20 may be a paint layer directly formed on the substrate 11 and in the receiving groove 12 by spray painting. The paint used to form the decorative layer 20 may mainly contain an acrylic resin, which is an elastic resin. Alternately, the decorative layer 20 may be made of other polymer materials.

The corona layer 30 is formed by corona treating the decorative layer 20 disposed in the receiving groove 12 in a corona device (not shown). During the formation of the corona layer 30, the remainder portion of the decorative layer 20 is shielded to avoid being badly affected. During the corona treatment, the electrical poles of the corona device discharge corona to produce a plurality of plasma to hit the surface of the decorative layer 20, allowing the molecules on the surface of the decorative layer 20 to be polarized and to form the corona layer 30. The corona layer 30 contains polar molecules, and has a greater surface tension than that of the decorative layer 20, thus the corona layer 30 can securely bond with the adhesive layer 50 and the metallic decorative element 40. The corona treatment may last for about 1 second to about 2 seconds. Also, the corona treatment cleans the corona layer 30, which further improves the bond of the adhesive layer 50 and the metallic decorative element 40 to the corona layer 30.

The metallic decorative element 40 may be made of stainless steel. The metallic decorative element 40 is inserted in the receiving groove 12 and is attached to the corona layer 30 by the adhesive layer 50.

An adhesion test was performed on the housing 10 of the exemplary embodiment using an adhesive tape. The housing 10 is first fastened, the adhesive tape is attached to the surface of the metallic decorative element 40. The adhesive tape is adhered to the metallic decorative element 40 for about five minutes. Then the adhesive tape is quickly pulled from the metallic decorative element 40 at a direction forming a 45° angle to the surface of the metallic decorative element 40. If the metallic decorative element 40 is not pulled away from the substrate 11 by the adhesive tape, the bond between the metallic decorative element 40 and the substrate 11 is qualified. The test indicated that the metallic decorative element 40 of the exemplary embodiment is not pulled away by the adhesive tape, therefore the bond between the metallic decorative element 40 and the substrate 11 is qualified.

The bond between the metallic decorative element 40 and the substrate 11 may be further enhanced by the forming of the receiving groove 12. However, even if the receiving groove 12 is not defined, the metallic decorative element 40 also has a good bond to the substrate 11.

A corona layer 30 is formed on the housing 10 for combining a metallic decorative element 40 on the housing 10, which effectively improves the bond between the metallic decorative element 40 and the substrate 11.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A housing, comprising:
a substrate;
a decorative layer formed on the substrate, a portion of the decorative layer defining a corona layer, the corona layer comprising polarized molecules; and
a metallic decorative element bonded the corona layer.

2. The housing as claimed in claim 1, wherein the decorative layer is a pain layer comprising acrylic resin.

3. The housing as claimed in claim 1, wherein the corona layer has a greater surface tension than that of the decorative layer.

4. The housing as claimed in claim 1, wherein the metallic decorative element is made of stainless steel.

5. The housing as claimed in claim 1, wherein the substrate defines a receiving groove in one surface of the substrate, the decorative layer is formed on the surface of the substrate and in the receiving groove, the portion of the decorative layer disposed in the receiving groove defines the corona layer.

6. The housing as claimed in claim 1, wherein further comprising an adhesive layer formed between the corona layer and the metallic decorative element.

7. The housing as claimed in claim 1, wherein the substrate is made of plastic, metal, or ceramic.

8. An electronic device, comprising:
a main body; and
a housing assembled to the main body, the housing comprising:
a substrate;
a decorative layer formed on the substrate, a portion of the decorative layer defining a corona layer, the corona layer comprising polarized molecules; and
a metallic decorative element bonded the corona layer.

9. The electronic device as claimed in claim 8, wherein the decorative layer is a pain layer comprising acrylic resin.

10. The electronic device as claimed in claim 8, wherein the corona layer has a greater surface tension than that of the decorative layer.

11. The electronic device as claimed in claim 8, wherein the metallic decorative element is made of stainless steel.

12. The electronic device as claimed in claim 8, wherein the substrate defines a receiving groove in one surface of the substrate, the decorative layer is formed on the surface of the substrate and in the receiving groove, the portion of the decorative layer disposed in the receiving groove defines the corona layer.

13. The electronic device as claimed in claim 8, wherein the housing further comprises an adhesive layer formed between the corona layer and the metallic decorative element.

14. The electronic device as claimed in claim 8, wherein the substrate is made of plastic, metal, or ceramic.
